(19) United States
(12) Patent Application Publication
(10) Pub. No.: US 2016/0176748 A1
(43) Pub. Date: Jun. 23, 2016

(54) A SEALING METHOD FOR THE GLASS PLATE

(71) Applicant: Yawei LIU, Shenzhen, Guangdong (CN)

(72) Inventor: Yawei LIU, Shenzhen, Guangdong (CN)

(21) Appl. No.: 14/131,290

(22) PCT Filed: Sep. 6, 2013
(86) PCT No.: PCT/CN2013/083047

§ 371 Date: Jan. 7, 2014

(30) Foreign Application Priority Data
Aug. 28, 2013 (CN) 201310381780.4

(51) Int. Cl. C03B 23/24; H01L 51/52

(52) U.S. Cl. CPC C03B 23/245; H01L 51/5246

(57) ABSTRACT

A sealing method for the glass plate comprises the following steps: Step 1) forming a glass hollowing area on the first glass plate for receiving the electronic components on the second glass plate; Step 2) dividing two glass sealing areas respectively from the glass plates, the two glass sealing areas are aligned to each other with the glass plates face to face; Step 3) filling the inactive gas into an attaching apparatus to adhere the two glass plate together, the atmospheric pressure in the glass hollowing area is 0.95˜1.0 atm; Step 4) moving the laser along the glass sealing area to weld the two glass plates together. During the welding process of the glass plates, the two glass plate can be adhered together without adhesive or glass dust. The environment pollution will be reduced. The produce processes will be simplified without the coating or wiping off the dissolvent processes.

### FIELD OF THE INVENTION

The invention relates to a sealing method for the glass plate, more particularly relates to no-adhesive sealing method for glass plate.

### BACKGROUND OF THE INVENTION

In the display field, the LCD and OLED display are displaced the CRT display step and step. The plane light source is a new-style source. The performance of the electrical equipment depends on the sealing and welding effect between the two glass plates.

The traditional glass plate can be sealed with UV curing technology or frit sealing technology. In the UV curing technology, no or little dissolvent shall be used. So the energy consumption is low. The low-temperature solidifying or heat reactive material also can be used. With fast curing, high efficient and coving a little area of curing equipment, the UV curing technology can be applied in high speed production line. However, because of the UV glue adhered the two glass plate is organic material, the gap of molecule is larger after solidifying. Easy to lead the water vapor or oxygen enter the inside sealing area through the glass plate. Therefore, the UV curing technology is more suitable for the field with no too sensitive to water vapor and oxygen, for example, the LCD field.

The frit sealing technology is a new sealing technology for glass plate. The glass dust can be disposed into viscous solution to coating on the sealing glass plate. One of the glass plate can be adhered to the other glass plate after heating the solvent removal. And then the glass dust can be flash burn to melt on laser. Finally, the two glass plates can be adhered together. In the frit sealing processes, the inorganic package material can be applied to be sealing material, so the ability is higher that resisting the water vapor and oxygen, so it is more suitably to the OLED technology that sensitive to water vapor or oxygen. Nowadays, the frit sealing patents are monopolized by several foreign companies.

However, using the UV curing technology, the UV glue can be used to be adhesive. Not only increase the process of the coating on the glass plate with adhesive, but also increase the adhesive cost. Using the frit sealing technology, the glass dust can be used to be adhesive that it also increase the coating process of the glass dust. If the adhesion of the glass dust is bad, the sealing of the glass plates will be defeated.

Therefore, it is necessary to provide a no-adhesive sealing method with simply process, low cost and fastness combined the glass plate.

### SUMMARY OF THE INVENTION

To overcome the above disadvantages, the main purpose of the present invention is provided a no-adhesive sealing method for glass plate with simply procedure, low cost and lesser equipment investment.

The present invention provides a sealing method for the glass plate which comprising the following steps:

Step 1) forming a glass hollowing area on the first glass plate for receiving the electronic components on the second glass plate;

Step 2) dividing two glass sealing areas respectively from the first glass plates and the second glass plates, the two glass sealing areas are aligned to each other with the glass plates face to face;

Step 3) filling the inactive gas into an attaching apparatus to adhere the two glass plate together;

Step 4) moving the laser along the glass sealing area to weld the two glass plates together.

In the preferred embodiment, the depth of the glass hollowing area is 10 μm-50 μm, preferably for 20 μm-40 μm. The depth of the glass hollowing area is larger than the height of the electronic components 20 μm. The width of the glass hollowing area is 400 μm-2000 μm, preferably for 800 μm-1500 μm. The glass hollowing area is made by polishing or etching. The laser is emitted from the CO2laser. The wavelength of the laser is 800 nm˜1200 nm, preferably for 900 nm˜1000 nm.

In the preferred embodiment, in step 3) the two glass plates can be adhered together in the sealing environment with inactive gas. The atmospheric pressure in the glass hollowing area is 0.95˜1.0 atm. When the two glass plates close to each other, the attaching apparatus can be vacuumized to keep the atmospheric pressure between the glass plates is less than or equal to 1.0 atm after adhered together. The inactive gas filling is nitrogen.

In the preferred embodiment, further comprising step 5) cutting edge of the welded glass plate.

Compared to the prior art, the present invention no-adhesive sealing method for glass plate, during the welding process of the two glass plate, the two glass plate can be adhered together without adhesive or glass dust. As a result, the environment pollution will be reduced, and the produce processes will be simplified without the coating or wiping off the dissolvent processes. The number of equipments also can be reduced. The investment of the equipment will be reduced. In the inactive gas space, the glass plates will be welding by laser to attach together without adhesive. In addition, before the laser welding, the surface of the two glass plate can be adhered to each other closely to ensure them adhered together in align and avoid the following disadvantage, for example, the uneven coating of the glass dust or adhesive, the glass dust solidified after welding and the oxygen or water vapor is inserted the gap between the frit plate and the TFT plate. Compared with the prior art, the sealing method will improve the good product rate on the sealing process.

### BRIEF DESCRIPTION OF THE DRAWINGS

FIG. 1 is a side view of the glass plate by the no-adhesive sealing method for glass plate; and

FIG. 2 is a schematic perspective view of the glass plate by the no-adhesive sealing method for glass plate.

### DETAILED DESCRIPTION OF THE PREFERRED EMBODIMENTS

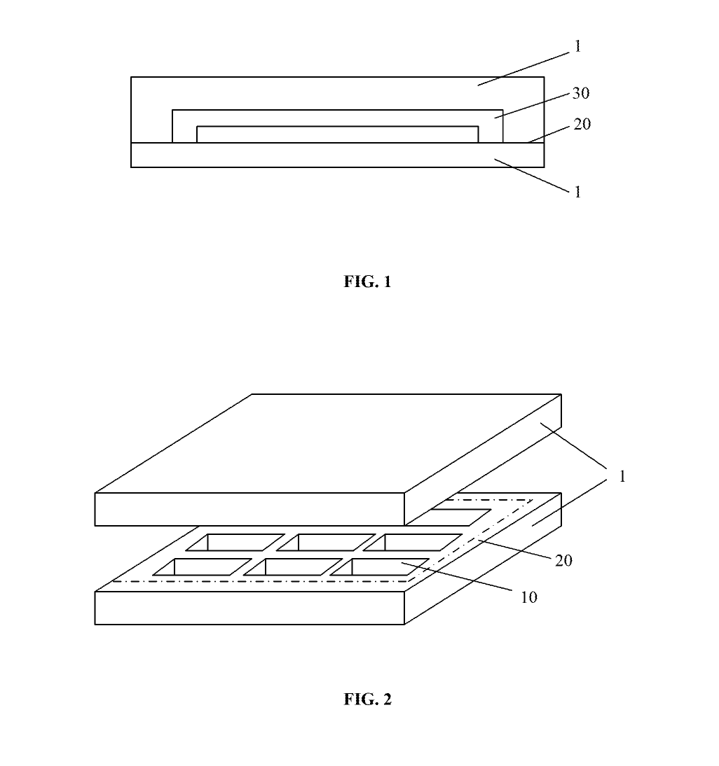

Refer to FIG. 1 and FIG. 2, for simplify the traditional sealing method for glass plate, the present invention provided an improved no-adhesive sealing method for the glass plate comprises the following steps:

Step 1) forming a glass hollowing area 10 on the first glass plate 1 for receiving the electronic components on the second glass plate 1;

Step 2) dividing two glass sealing areas 20 respectively from the first glass plates and the second glass plates 1, the two glass sealing areas 20 are aligned to each other with the glass plates face to face;

Step 3) filling the inactive gas into an attaching apparatus to adhere the two glass plate together;

Step 4) moving the laser along the glass sealing area 20 to weld the two glass plates together.

Firstly, washing and etching the two glass plate 1, and then forming the glass hollowing area 10 on the first glass plate according to a predetermined pattern, there is plurality of electronic components mounted on the second glass plate. The electronic components are covered in the glass hollowing area 10.

The glass sealing area 20 are divided from the outer border of the glass plate for confining the laser welding area more clearly to make the two glass plates butt-joint in order. When the two glass plates are plating on opposite, the glass sealing areas 20 will be aligned for laser welding. The surface of the glass plate is a plane so as to ensure the two glass plate attached to each other more closely. In the present invention, the depth of the glass hollowing area 20 is 10 μm-50 μm, preferably for 20 μm-40 μm; the depth of the glass hollowing area is larger than the height of the electronic components 20 μm. Then a space will come into being with the electronic components inserting into the glass hollowing area for avoiding the glass plate breaking out by the pressure of the electronic components. The width of the glass hollowing area is 400 μm-2000 μm, preferably for 800 μm-1500 μm. The four corners can be selected of right angle, filleted corner or other shaped corner.

Secondly, put the two glass plates oppositely, then the glass sealing area 20 on the glass hollowing area are aligned with for ensure the precision of the sealing process.

Thirdly, putting the two glass plates into the attaching apparatus and filling the inactive gas into it.

In the present invention, the two glass plates can be adhered together in the sealing environment with inactive gas. The atmospheric pressure in the glass hollowing area is 0.95-1.0 atm. When the two glass plates close to each other, the attaching apparatus can be vacuumized to keep the atmospheric pressure between the glass plates is less than or equal to 1.0 atm after adhered together. For avoiding larger atmospheric pressure between the two glass plates to make the glass plate float up with the atmospheric pressure is equal to and preventing affecting the sealing quality by the gap between the two glass plates on welding. The inactive gas filling is nitrogen. The glass plate and the oxygen are separated with the inactive gas so as to prevent the glass plate oxidized on welding.

And then, welding on the glass sealing area 20 of the glass hollowing area 10 by CO₂ laser or other lasers. With adjusting the focal distance, the size of the focal spot and the laser intensity, lead the focal spot focus on the interface of the two glass plates. The focal spot of the laser is moving along the glass sealing line to weld the two glass plates together. Therein, the wavelength of the laser is 800 nm˜1200 nm, preferably for 900 nm˜1000 nm.

Finally, cutting edge of the welded glass plate to achieve a no-adhesive glass produce.

The present invention no-adhesive sealing method for glass plate, during the welding process of the two glass plate, the two glass plate can be adhered together without adhesive or glass dust. As a result, the environment pollution will be reduced, and the produce processes will be simplified without the coating or wiping off the dissolvent processes. The number of equipments also can be reduced, such as UV coating machine, low glass coating machine and low glass glue drying machine. The investment of the equipment will be reduced 50% to cut down the whole produce cost. In the inactive gas space, the glass plates will be welding by laser to attach together without adhesive. In addition, before the laser welding, the surface of the two glass plate can be adhered to each other closely to ensure them adhered together in align and avoid the following disadvantage, for example, the uneven coating of the glass dust or adhesive, the glass dust solidified after welding and the oxygen or water vapor is inserted the gap between the two glass plates. Compared with the prior art, the sealing method will improve the good product rate on the sealing process.

What is claimed is:

1. A sealing method for the glass plate comprising the following steps:
Step 1) forming a glass hollowing area on the first glass plate for receiving the electronic components on the second glass plate;
Step 2) dividing two glass sealing areas respectively from the first glass plates and the second glass plates, the two glass sealing areas are aligned to each other with the glass plates face to face;
Step 3) filling the inactive gas into an attaching apparatus to adhere the two glass plate together, the atmospheric pressure in the glass hollowing area is 0.95˜1.0 atm; and
Step 4) moving the laser along the glass sealing area to weld the two glass plates together.

2. The sealing method for the glass plate according to claim 1, wherein in step 3) when the two glass plates close to each other, the attaching apparatus can be vacuumized to keep the atmospheric pressure between the two glass plates is less than or equal to 1.0 atm after adhering together.

3. The sealing method for the glass plate according to claim 1, wherein in step 4) the wavelength of the laser is 800 nm˜1200 nm.

4. The sealing method for the glass plate according to claim 3, wherein in step 4) the wavelength of the laser is 900 nm˜1000 nm.

5. The sealing method for the glass plate according to claim 1, wherein the depth of the glass hollowing area is 10 μm-50 μm.

6. The sealing method for the glass plate according to claim 5, wherein the depth of the glass hollowing area is 20 μm-40 μm.

7. The sealing method for the glass plate according to claim 5, wherein the depth of the glass hollowing area is larger than the height of the electronic components 20 μm.

8. The sealing method for the glass plate according to claim 1, wherein the width of the glass hollowing area is 400 μm-2000 μm.

9. The sealing method for the glass plate according to claim 8, wherein the width of the glass hollowing area is 800 μm-1500 μm.

10. The sealing method for the glass plate according to claim 2, further comprising step 5) cutting edge of the welded glass plate.

11. The sealing method for the glass plate according to claim 1, wherein in the step 1) the glass hollowing area is made by polishing or etching.

12. The sealing method for the glass plate according to claim 4, wherein in the step 4) the laser is emitted from the CO₂ laser.

13. The sealing method for the glass plate according to claim 1, wherein in the step 3) the inactive gas is nitrogen.

14. A sealing method for the glass plate comprising the following steps:
Step 1) forming a glass hollowing area on the first glass plate for receiving the electronic components on the second glass plate;
Step 2) dividing two glass sealing areas respectively from the first glass plates and the second glass plates, the two glass sealing areas are aligned to each other with the glass plates face to face;
Step 3) filling the inactive gas into an attaching apparatus to adhere the two glass plate together; and
Step 4) moving the laser along the glass sealing area to weld the two glass plates together.

15. The sealing method for the glass plate according to claim 14, wherein the atmospheric pressure in the glass hollowing area is 0.95˜1.0 atm.

16. The sealing method for the glass plate according to claim 15, wherein in step 3) when the two glass plates close to each other, the attaching apparatus can be vacuumized to keep the atmospheric pressure between the two glass plates is less than or equal to 1.0 atm after adhering together.

17. The sealing method for the glass plate according to claim 14, wherein in step 4) the wavelength of the laser is 800 nm˜1200 nm, the depth of the glass hollowing area is 10 μm-50 μm, the width of the glass hollowing area is 400 μm-2000 μm.

18. The sealing method for the glass plate according to claim 17, wherein the depth of the glass hollowing area is larger than the height of the electronic components 20 μm.

19. The sealing method for the glass plate according to claim 14, further comprising step 5) cutting edge of the welded glass plate.

20. The sealing method for the glass plate according to claim 14, wherein in the step 1) the glass hollowing area is made by polishing or etching.
